(19) United States
(12) Patent Application Publication
(10) Pub. No.: US 2019/0123716 A1
(43) Pub. Date: Apr. 25, 2019

(54) MICROCAPPED PACKAGE HAVING POLYMER STANDOFF

(71) Applicant: Avago Technologies general IP (Singapore) Pte. Ltd, Singapore (SG)

(72) Inventors: Steven Martin, Fort Collins, CO (US); Andrew Barfknecht, Menlo Park, CA (US); Nathan Perkins, Windsor, CO (US); Vikram Patil, Fort Collins, CO (US)

(21) Appl. No.: 15/792,417

(22) Filed: Oct. 24, 2017

(51) Int. Cl. H03H 9/52; H03H 9/02

(52) U.S. Cl. CPC H03H 9/525; H03H 9/02535; H03H 9/02015

(57) ABSTRACT

An apparatus includes: a substrate; a lid disposed over the substrate, and comprising posts disposed around a perimeter of the substrate, the posts enclosing a cavity between the lid and the substrate; an electronic device disposed over an upper surface of the substrate, and in the cavity; an electrical contact pad; and an electrically insulating layer disposed between the electrical contact pad and an upper surface of the lid.

### BACKGROUND

Electrical resonators are widely incorporated in modern electronic devices. For example, in wireless communications devices, radio frequency (RF) and microwave frequency resonators are used in filters, such as filters having electrically connected series and shunt resonators forming ladder and lattice structures. The filters may be included in a multiplexer, such as a duplexer, for example, connected between an antenna (or multiple antennas as in the case of multiple input, multiple output (MIMO) designs) and a transceiver for filtering received and transmitted signals, typically within a predetermined radio frequency band. Other types of multiplexers in which the filters may be included are diplexers, triplexers, quadplexers, quintplexers and the like, for example. The multiplexer interfaces between the antenna and each of various networks to enable transmitting signals on different transmit (uplink) frequencies and receiving signals on different receive (downlink) frequencies. The filters associated with the multiplexer typically include band pass filters, which provide passbands for passing various transmitted and received signals through relatively narrow frequency bands (blocking all signals with frequencies outside the passbands).

As will be appreciated, it is desirable to reduce the size of components of electronic devices. Many known filter technologies present a barrier to overall system miniaturization. With the need to reduce component size, a class of resonators based on the piezoelectric effect has emerged. In piezoelectric-based resonators, acoustic resonant modes are generated in the piezoelectric material. These acoustic waves are converted into electrical waves for use in electrical applications.

One type of piezoelectric resonator is a Bulk Acoustic Wave (BAW) resonator. The BAW resonator has the advantage of small size and lends itself to Integrated Circuit (IC) manufacturing tools and techniques. The BAW includes an acoustic stack. The acoustic stack includes, inter alia, a layer of piezoelectric material disposed between two electrodes. Acoustic waves achieve resonance across the acoustic stack, with the resonant frequency of the waves being determined by the materials in the acoustic stack.

Film bulk acoustic resonator (FBAR) filters are one type of BAW filters. FBAR technology is characterized by superior performance in terms of Q over frequency, effective coupling coefficient kt2, and precise frequency control. These FBAR performance characteristics translate to superior product performance in terms of (low) insertion loss, (satisfactory) roll off characteristics at filter edge, (optimum) isolation, and (highest) nonlinearity performance.

FBARs include a piezoelectric layer sandwiched between two metal electrodes, i.e., a top metal electrode and a bottom metal electrode. FBARs are placed above an air cavity, and rely on air cavity packaging technology to achieve required performance characteristics. As a result, air cavities below FBARs must necessarily be robust and must not interfere with the resonator frequency centering, Q values, or nonlinearities.

Known packaging for FBAR(s) may include a semiconductor microcap lid placed over the FBAR(s) and the above-noted air cavities formed below the FBAR(s). The microcap lid may be held above the FBAR(s) by posts that are formed from the same material as the microcap lid and that are integral with the microcap lid wafer. The microcap lids are a wafer-level silicon cap (microcap) micromachined from a high resistivity wafer.

Parasitic contributions from the microcap lid wafer/microcap lid degrade linear performance characteristics of the packaged FBAR product. The parasitic contributions arise from the bulk conductivity of the semiconductor material (e.g., silicon) used for the microcap lid, as well as surface capacitances and inversions, plus the charging and discharging of semiconductor trap states. Any solution to the parasitic contributions that provides higher performance at a lower cost should not interfere with the air cavities below the FBAR, nor adversely affect the frequency centering, Q values, or nonlinearities.

What is needed are package structures that overcome at least the shortcomings of known package structures described above.

### BRIEF DESCRIPTION OF THE DRAWINGS

The example embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals, refer to like elements.

FIG. 1 is a cross-sectional view of an apparatus according to a representative embodiment.

FIG. 2 is a cross-sectional view of an apparatus according to a representative embodiment.

FIGS. 3A-3K are cross-sectional views of a process for fabricating an apparatus according to a representative embodiment.

FIG. 4 is a simplified schematic block diagram of an acoustic filter in accordance with a representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the representative embodiments. Such methods and apparatuses are clearly within the scope of the present teachings.

It is to be understood that the terminology used herein is for purposes of describing particular embodiments only, and is not intended to be limiting. Any defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to with acceptable limits or degree. For example, ‘substantially cancelled’ means that one skilled in the art would consider the cancellation to be acceptable.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be “below” that element. Similarly, if the device were rotated by 90° with respect to the view in the drawings, an element described “above” or “below” another element would now be “adjacent” to the other element; where “adjacent” means either abutting the other element, or having one or more layers, materials, structures, etc., between the elements.

In accordance with a representative embodiment, an apparatus comprises: a substrate; a lid disposed over the base substrate, and comprising posts disposed around a perimeter of the substrate, the posts enclosing a cavity between the lid and the substrate; an electronic device disposed over an upper surface of the substrate, and in the cavity; an electrical contact pad; and an electrically insulating layer disposed between the electrical contact pad and an upper surface of the lid.

In accordance with another representative embodiment, an apparatus comprises: a substrate; a lid disposed over the base substrate, and comprising posts disposed around a perimeter of the substrate, the posts enclosing a cavity between the lid and the substrate; an electrical filter comprising a plurality of acoustic resonators disposed over an upper surface of the substrate, and in the cavity; an electrical contact pad; and an electrically insulating layer disposed between the electrical contact pad and an upper surface of the lid.

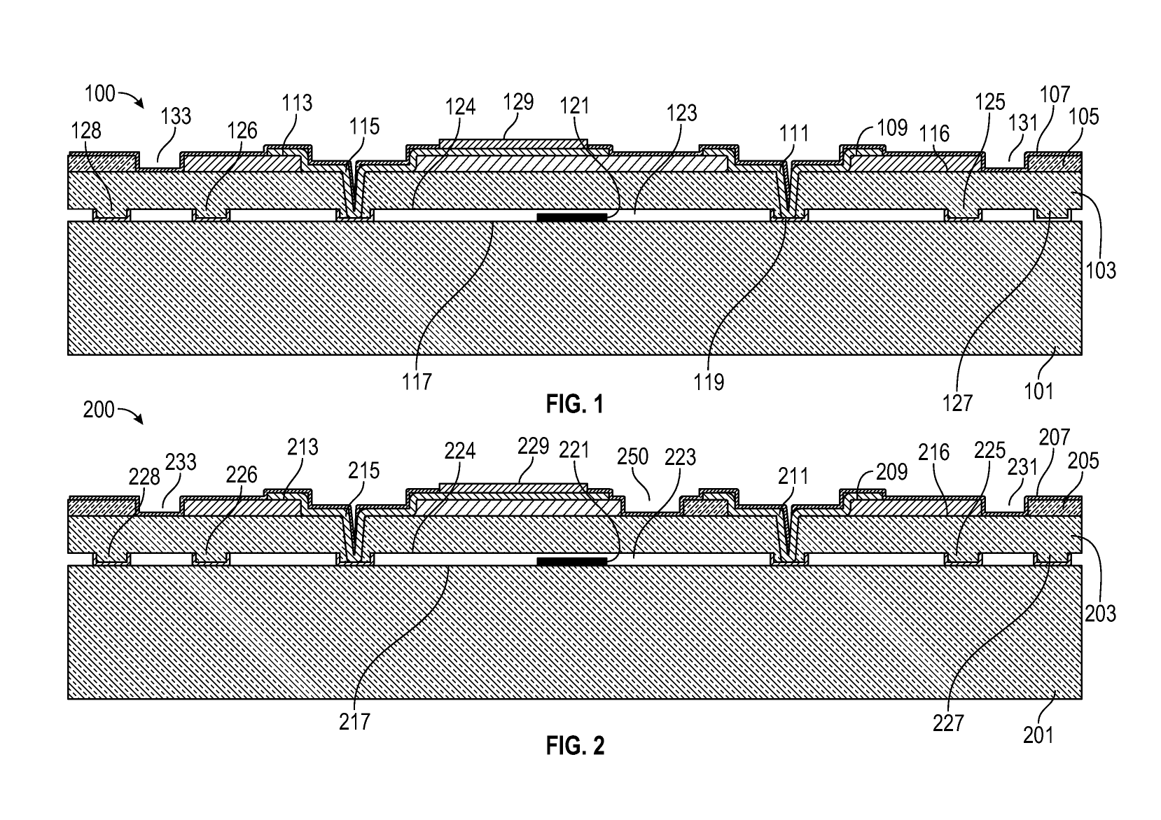

FIG. 1 is a cross-sectional view of an apparatus 100 according to a representative embodiment. The apparatus 100 may also be a component of a wafer-level package for reasons that will become clearer as the present description continues.

The apparatus 100 comprises a substrate 101, and a lid 103 disposed thereover. An electrically insulating layer 105 is disposed over an upper surface 117 of the substrate 101, and between the substrate 101 and a first electrical contact pad 109 of a first electrically conductive via 111, and a second electrical contact pad 113 of a second electrically conductive via 115. A passivation layer 107 is disposed over respective upper surfaces of the electrically insulating layer 105, and the first and second electrical contact pads 109, 113.

As shown in FIG. 1, and as will be described more fully below, substantial areal portions of the first and second electrical contact pads 109, 113 are prevented from making direct contact with an upper surface 116 of the lid 103. Similarly, the passivation layer 107 is generally not in direct contact with the upper surface 116 of the lid 103; rather the electrically insulating layer 105, first and second electrical contact pads 109, 113, and the first and second electrically conductive vias 111, 115 are beneficially disposed between the passivation layer 107 and the upper surface 116 of the lid 103.

The first and second electrical contact pads 109, 113 make electrical connections to circuitry (not shown) through first and second electrically conductive vias 111, 115, respectively. Other electrical circuitry (not shown) disposed over the upper surface 117 of the substrate 101, in addition to providing other electrical connections, provides electrical connections between the first and second electrically conductive vias 111, 115, and electronic device 121 disposed over the upper surface 117 of the substrate 101.

The electronic device 121 is disposed in a cavity 123 formed between a lower surface 124 of the lid 103, and the upper surface 117 of the substrate 101. First˜fourth standoffs 125-128, which are illustratively thermal-compression bonded to the upper surface 117 of the substrate 101, border the cavity 123. In this way, the cavity 123 is enclosed, being formed by opposing surfaces 117, 124; and first and second standoffs 125, 126. In certain representative embodiments, by known methods and materials, the lid 103 is adhered to the substrate 101 using first and second standoffs 125, 126 so that the cavity 123 is hermetically sealed to a desired level of hermeticity. The structure comprising the lid 103 disposed over a substrate 101 and providing the cavity 123 is often referred to as a “microcap” structure. Further details of microcap structures may be found in commonly-owned U.S. Pat. Nos. 6,429,511; 6,777,267; 7,422,929; 8,102,044; 8,232,845; 8,680,944; and 8,946,877, the entire disclosures of which are specifically incorporated herein by reference.

The second electrical contact pad 113 is electrically connected to an electrical contact 129, which is disposed over the electrically insulating layer 105, and thus is not in contact with the upper surface 116 of the lid 103. The first electrical contact pad 109 makes electrical connections to circuitry (not shown), which may be disposed over the upper surface 116 of the lid 103. Such circuitry may be as described in the above-incorporated U.S. Pat. No. 8,232,845 suitably modified according to the present teachings.

As will be appreciated, the electrical contact 129 may be a signal contact, or a ground contact. In certain embodiments, the electrical contact 129 has an electrically conductive pillar (not shown) for making further electrical connections disposed thereover, and allows the apparatus 100, once singulated, to be flip-chip mounted to another substrate such as a printed circuit board (PCB) (not shown). Further details of electrically (and thermally) conductive pillars may be found at least in commonly owned U.S. Pat. Nos. 7,202,560; 8,314,472; 8,344,504; 9,324,557; 9,444,428; and 9,576,920. The disclosures of these patents are specifically incorporated herein by reference.

In accordance with a representative embodiment, the substrate 101 and the lid 103 are semiconductor materials, illustratively silicon, and the first and second electrical contact pads 109, 113 are plated copper, or another suitable metal or metal alloy. In known structures, such contact pads are disposed directly on the semiconductor substrate. In such known structures, charging and discharging in the contact pads result in voltages that generate depletion and enhancement regions at the surface of the semiconductor layer used for the lid. As will be appreciated, the generation of depletion and enhancement regions results in spurious currents in the lid. These spurious currents can reduce the desired linear performance, and can contribute to undesired parasitic capacitances. However, by the present teachings, the electrically insulating layer 105 is provided between a significant area of overlap of the first and second electrical contact pads 109, 113, and the electrical contact 129, with the upper surface 116 of the lid 103. As such, the electrically insulating layer 105 substantially electrically isolates the first and second electrical contact pads 109, 113, and the electrical contact 129 from the lid 103. Beneficially, therefore, the electrically insulating layer 105 at least reduces the incidence of unwanted depletion and enhancement regions, and spurious currents.

Notably, in certain representative embodiments, approximately 30% to approximately 100% (i.e., entire area) of an area of overlap of each of the first electrical contact pad 109, the second electrical contact pad 113, and the electrical contact 129 with the upper surface 116 of the lid 103 has the electrically insulating layer 105 disposed between the respective first electrical contact pad 109, the second electrical contact pad 113, and the electrical contact 129, and the upper surface 116 of the lid 103. In one representative embodiment, approximately 88% of the area of overlap of each of the first electrical contact pad 109 and the second electrical contact pad 113 with the upper surface 116 of the lid 103 has the electrically insulating layer 105 disposed between the respective first electrical contact pad 109, the second electrical contact pad 113, and the upper surface 116 of the lid 103.

More generally, electrically conductive structures (e.g., first and second electrical contact pads, 109, 113; electrical contact 129; circuitry (not shown) disposed over the upper surface 116 of the lid 103; and other components to which voltages are applied) may have the electrically insulating layer 105 disposed beneath to avoid their directly contacting the upper surface 116.

Similarly, as noted above, in accordance with the present teachings, the passivation layer 107 is generally not in direct contact with the upper surface 116 of the lid 103. In certain representative embodiments, the passivation layer 107 is silicon nitride (Si₃N₄) deposited by a known chemical vapor deposition technique, such as plasma-enhanced chemical vapor deposition (PECVD). As will be appreciated, when deposited by such methods directly on the upper surface of the lid 103, which is illustratively silicon, a comparatively poor interface results, and trap charges can result at the interface of the passivation layer 107 and the lid 103. These trapped charges can also result in parasitic currents and capacitances, which as noted above can be deleterious to the desired linear performance of the apparatus 100. However, by the present teachings, the electrically insulating layer 105 is generally provided in locations of the upper surface 116 of the lid 103, which are exposed, and which would otherwise be in direct contact of the passivation layer 107. Thus, because the electrically insulating layer 105 is disposed between the upper surface 116 of the lid 103 and the passivation layer 107, these parasitics are substantially reduced, and linear performance of the electronic device 121 is substantially identical to a structure not having the lid disposed over the substrate 101.

In accordance with a representative embodiment, the electrically insulating layer 105 is a photo-definable polymer layer. In a specific embodiment, the photodefinable polymer is an epoxy-based negative tone photosensitive material. Illustratively, the photodefinable polymer is SUB, which is commercially available from MicroChem Corporation Westborough, Mass. (USA); or photosensitive epoxy laminate TMMF, which is commercially available from Tokyo Ohka Kogyo (TOK), Japan. More generally, the photodefinable polymer used to form the electrically insulating layer 105 may be a dry film photoresist, or a spin-on resist. Beneficially, the electrically insulating layer 105 has a volume resistivity in the range of approximately 1.0×10¹⁴ Ω-cm to approximately 1.0×10¹⁵ Ω-cm. In certain embodiments, the electrically insulating layer 105 has a volume resistivity in the range of approximately 1.8×10¹⁴ Ω-cm to approximately 2.8×10¹⁴ Ω-cm. Similarly, the electrically insulating layer 105 has a dielectric constant in the range of approximately 2.0 V/cm and approximately 5.0 V/cm. In certain embodiments, the electrically insulating layer 105 has a dielectric constant in the range of approximately 3.0 V/cm to approximately 4.1 V/cm. Finally, since capacitance is directly proportional to the relative permittivity, and inversely proportional to the distance between conductive ‘plates,’ in order to reduce the capacitive coupling of the electrical components (e.g., first and second electrical contact pads 109, 113) with the underlying lid 103, it is useful to provide a comparatively thick electrically insulating layer 105 with a dielectric constant in the range noted above. In accordance with a representative embodiment, the electrically insulating layer 105 has a thickness in the range of approximately 10 μm to approximately 40 μm.

As will become apparent as the present description continues, the photodefinability of the electrically insulating layer 105 is useful to provide the layer over selected portions of the upper surface 116 of the lid 103. However, the electrically insulating layer 105 may be another type of material amenable to known semiconductor processing methods. To this end, material of the electrically insulating layer 105 generally has the insulating properties as described above.

As noted above, apparatus 100 may also be a component of a wafer-level package. To this end, a plurality of apparatuses 100 are fabricated in a single wafer. After completion of the wafer-level fabrication, individual die including one or more electronic devices 121 disposed in one or more cavities 123 are provided by known singulation methods. As will be appreciated, suitable dicing methods are applied to first and second saw streets 131, 133 to effect the singulation. Notably, it is beneficial to remove the electrically insulating layer 105 from the upper surface 116 in the locations of the first and second saw streets 131,133 to avoid delamination of the electrically insulating layer 105.

Finally, electrical connections (not shown), useful for example during fabrication of the apparatus 100, may be provided through the saw streets 131, 133, and severed by the dicing to provide the individual die. Details of such electrical connections may be found in commonly-owned U.S. patent application Ser. No. 15/720,374 to Gilbert, et al., filed on Sep. 29, 2017, and specifically incorporated herein by reference.

A variety of devices, structures thereof, materials and methods of fabrication are contemplated for the first and second acoustic resonators 118, 120 of the apparatus 100. Various details of such FBAR and SMR devices contemplated for use as the first and second acoustic resonators 118, 120 of the apparatus 100, and corresponding methods of fabrication may be found, for example, in one or more of the following U.S. patent documents: U.S. Pat. No. 6,107,721, to Lakin; U.S. Pat. Nos. 5,587,620, 5,873,153, 6,507,983, 7,388,454, 7,629,865, 7,714,684, and 8,436,516 to Ruby et al.; U.S. Pat. Nos. 7,369,013, 7,791,434, 8,188,810, and 8,230,562 to Fazzio, et al.; U.S. Pat. No. 7,280,007, U.S. Patent Application Publication Nos. 20150244347 and 20140174908 to Feng et al.; U.S. Pat. Nos. 8,248,185, and 8,902,023 to Choy, et al.; U.S. Pat. No. 7,345,410 and U.S. Patent Application Publication No. 20150326200, to Grannen, et al.; U.S. Pat. No. 6,828,713 to Bradley, et al.; U.S. Pat. Nos. 7,561,009, 7,358,831, and U.S. Patent Application Publication No. 20140246305, to Larson, III et al.; U.S. Pat. No. 9,197,185 to Zou, et al.; U.S. Patent Application Publication No. 20120326807 to Choy, et al.; U.S. Pat. Nos. 9,243,316 and 8,673,121 to Larson III, et al.; U.S. Pat. No. 8,981,876 to Jamneala et al.; U.S. Pat. No. 9,479,139 to Ruby, et al.; U.S. Patent Application Publication No. 20130015747 to Ruby, et al.; U.S. Pat. No. 9,197,185 to Zou, et al.; U.S. Pat. No. 9,484,882 to Burak, et al.; U.S. Pat. No. 9,679,765, and U.S. Patent Application Publication 20140132117, to John L. Larson III; U.S. Pat. Nos. 9,136,819 and 9,602,073 to Grannen, et al.; U.S. Pat. Nos. 9,450,167, and 9,590,165 to Zou, et al.; U.S. Pat. No. 9,455,681 to Feng, et al; U.S. Patent Application Publication No. 20150311046 to Yeh, et al.; and U.S. patent application Ser. No. 15/661,468 to Ruby, et al., and filed on Jun. 27, 2017. The entire disclosure of each of the patents, patent application publications, and patent application listed above are hereby specifically incorporated by reference herein. It is emphasized that the components, materials and methods of fabrication described in these patents and patent applications are representative, and other methods of fabrication and materials within the purview of one of ordinary skill in the art are also contemplated.

FIG. 2 is a cross-sectional view of an apparatus 200 in accordance with a representative embodiment. Many aspects and details of the various components of the apparatus 200 are common to those described above in connection with representative embodiments of FIG. 1. These common aspects and details are not necessarily repeated, but are nonetheless contemplated by the description of the apparatus 200. Like apparatus 100, the apparatus 200 may also be a component of a wafer-level package.

The apparatus 200 comprises a substrate 201, and a lid 203 disposed thereover. An electrically insulating layer 205 is disposed over an upper surface 217 of the substrate 201, and between the substrate 201 and a first electrical contact pad 209 of a first electrically conductive via 211, and a second electrical contact pad 213 of a second electrically conductive via 215. A passivation layer 207 is disposed over respective upper surfaces of the electrically insulating layer 205, and the first and second electrical contact pads 209, 213.

As shown in FIG. 2, and as will be described more fully below, substantial areal portions of the first and second electrical contact pads 209, 213 are prevented from making direct contact with an upper surface 216 of the lid 203. Similarly, the passivation layer 207 is generally not in direct contact with the upper surface 216 of the lid 203; rather the electrically insulating layer 205, first and second electrical contact pads 209, 213, and the first and second electrically conductive vias 211, 215 are beneficially disposed between the passivation layer 207 and the upper surface 216 of the lid 203.

The first and second electrical contact pads 209, 213 make electrical connections to circuitry (not shown) through first and second electrically conductive vias 211, 215, respectively. Other electrical circuitry (not shown) disposed over the upper surface 217 of the substrate 201, in addition to providing other electrical connections, provides electrical connections between the first and second electrically conductive vias 211, 215, and an electronic device 221 disposed over the upper surface 217 of the substrate 201.

The electronic device 221 is disposed in a cavity 223 formed between a lower surface 224 of the lid 203, and the upper surface 217 of the substrate 201. First˜fourth standoffs 225-228, which are illustratively thermal-compression bonded to the upper surface 217 of the substrate 201, border the cavity 223. In this way, the cavity 223 is enclosed, being formed by opposing surfaces 217, 224; and first and second standoffs 225, 226. In certain representative embodiments, by known methods and materials, the lid 203 is adhered to the substrate 201 using first and second standoffs 225, 226, so that the cavity 223 is hermetically sealed to a desired level of hermeticity. The structure comprising the lid 203 disposed over a substrate 201 and providing the cavity 223 is often referred to as a “microcap” structure.

The second electrical contact pad 215 is electrically connected to an electrical contact 229, which is disposed over the electrically insulating layer 205, and thus is not in contact with the upper surface 216 of the lid 203. The first electrical contact pad 209 makes electrical connections to circuitry (not shown), which may be disposed over the upper surface 216 of the lid 203. Such circuitry may be as described in the above-incorporated U.S. Pat. No. 8,232,845 suitably modified according to the present teachings.

As will be appreciated, the electrical contact 229 may be a signal contact, or a ground contact. In certain embodiments, the electrical contact 229 has a conductive pillar (not shown) for making further electrical connections disposed thereover, and allows the apparatus 200, once singulated, to be flip-chip mounted to another substrate such as a printed circuit board (PCB) (not shown).

In accordance with a representative embodiment, the substrate 201 and the lid 203 are semiconductor materials, illustratively silicon, and the first and second electrical contact pads 209, 213 are copper, or another suitable metal or metal alloy. In known structures, such contact pads are disposed directly on the semiconductor substrate. In such known structures, charging and discharging in the contact pads results in voltages that generate depletion and enhancement regions at the surface of the semiconductor layer used for the lid. As will be appreciated, the generation of depletion and enhancement regions results in spurious currents in the lid. These spurious currents can reduce the desired linear performance, and can contribute to undesired parasitic capacitances. However, by the present teachings, the electrically insulating layer 205 is provided between a significant area of overlap of the first and second electrical contact pads 209, 213, and the electrical contact 229, with the upper surface 216 of the lid 203. The electrically insulating layer 205 is thus provided to substantially electrically isolate the first and second electrical contact pads 209, 213, and the electrical contact 229, from the lid 203. Beneficially, therefore, the electrically insulating layer 205 at least reduces the incidence of unwanted depletion and enhancement regions, and spurious currents.

Like embodiments described above, in certain representative embodiments, approximately 30% to approximately 100% (i.e., entire area) of an area of overlap of each of the first electrical contact pad 209, the second electrical contact pad 213, and the electrical contact 229 with the upper surface 216 of the lid 203 has the electrically insulating layer 205 disposed between the respective first electrical contact pad 209, the second electrical contact pad 213, and the electrical contact 229, and the upper surface 216 of the lid 203. In one representative embodiment, approximately 88% of the area of overlap of each of the first electrical contact pad 209 and the second electrical contact pad 213 with the upper surface 216 of the lid 203 has the electrically insulating layer 205 disposed between the respective first electrical contact pad 209, the second electrical contact pad 213, and the upper surface 216 of the lid 203. Notably, in certain embodiments, the electrically insulating layer 205 can by provided between the entire portions of the first and second electrical contact pads 209, 213 and the upper surface 216.

More generally, electrically conductive structures (e.g., first and second electrical contact pads, 209, 213; electrical contact 229; circuitry (not shown) disposed over the upper surface 216 of the lid 203; and other components to which voltages are applied) may have the electrically insulating layer 205 disposed beneath to avoid their directly contacting the upper surface 216 of lid 203.

Similarly, as noted above, in accordance with the present teachings, the passivation layer 207 is generally not in direct contact with the upper surface 216 of the lid 203. In certain representative embodiments, the passivation layer 207 is silicon nitride (Si₃N₄) and is deposited by a known chemical vapor deposition technique, such as plasma-enhanced chemical vapor deposition (PECVD). As will be appreciated, when deposited by such methods directly on the upper surface of the lid 203, which is illustratively silicon, a comparatively poor interface results, and trap charges can result at the interface of the passivation layer 207 and the lid 203. As noted above, by the present teachings, the electrically insulating layer 205 is generally provided in locations of the upper surface 216 of the lid 203, which are exposed, and over which the passivation layer 207 is provided, in order to reduce these parasitics to provide linear performance of the electronic device 221 that is substantially identical to a structure not having the lid disposed over the substrate 201. However, in certain areas of the upper surface 216 of the lid 203, the impact of direct contact of the passivation layer 207 with the upper surface 216 may not be great, for example, due to the comparatively small magnitude of the area. As such, for example, in an area 250 of the upper surface 216, the electrically insulating layer 205 is not provided between the passivation layer 207 and the upper surface 216.

In accordance with a representative embodiment, the electrically insulating layer 205 is a photo-definable polymer layer. In a specific embodiment, the photodefinable polymer is an epoxy-based negative tone photosensitive material. By way of example, the photodefinable polymer is SUB, which is commercially available from MicroChem Corporation Westborough, Mass. (USA); or photosensitive epoxy laminate TMMF, which is commercially available from Tokyo Ohka Kogyo (TOK), Japan. More generally, the photodefinable polymer used to form the electrically insulating layer 205 may be a dry film photoresist, or a spin-on resist. Beneficially, the electrically insulating layer 205 has a volume resistivity in the range of approximately1.0×10¹⁴ Ω-cm to approximately 1.0×10¹⁵ Ω-cm. In certain embodiments, the electrically insulating layer 205 has a volume resistivity in the range of approximately 1.8×10¹⁴ Ω-cm to approximately 2.8×10¹⁴ Ω-cm. Similarly, the electrically insulating layer 205 has a dielectric constant in the range of approximately 2.0 V/cm and approximately 5.0 V/cm. In certain embodiments, the electrically insulating layer 205 has a dielectric constant in the range of approximately 3.0 V/cm to approximately 4.1 V/cm. Finally, since capacitance is directly proportional to the relative permittivity, and inversely proportional to the distance between conductive ‘plates,’ in order to reduce the capacitive coupling of the electrical components (e.g., first and second electrical contact pads 209, 213) with the underlying lid 203, it is useful to provide a comparatively thick electrically insulating layer 205 with a dielectric constant in the range noted above. In accordance with a representative embodiment, the electrically insulating layer 205 has a thickness in the range of approximately 10 μm to approximately 50 μm.

As will become apparent as the present description continues, the photodefinability of the electrically insulating layer 205 is useful to provide the layer over selected portions of the upper surface 216 of the lid 203. However, the electrically insulating layer 205 may be another type of material amenable to known semiconductor processing methods. To this end, material of the electrically insulating layer 205 generally has the insulating properties as described above.

As noted above, apparatus 200 may also be a component of a wafer-level package. To this end, a plurality of apparatuses 200 is fabricated in a single wafer. After completion of the wafer-level fabrication, individual die including one or more electronic devices 221 disposed in one or more cavities 223 are provided by known singulation methods. As will be appreciated, suitable dicing methods are applied to first and second saw streets 231, 233 to effect the singulation. Notably, it is beneficial to remove the electrically insulating layer 205 from the upper surface 216 in the locations of the first and second saw streets 231,233 to avoid delamination of the electrically insulating layer 205.

Finally, electrical connections (not shown), useful for example during fabrication of the apparatus 200, may be provided through the saw streets 231, 233, and severed by the dicing to provide the individual die.

A variety of devices, structures thereof, materials, and methods of fabrication are contemplated for the electronic device 221. Like electronic device 121, the electronic device 221 may be an electronic device such as an electrical filter or multiplexer, comprising a film bulk acoustic wave resonator (FBAR) or solid mount acoustic wave resonator (SMR), such as those described above.

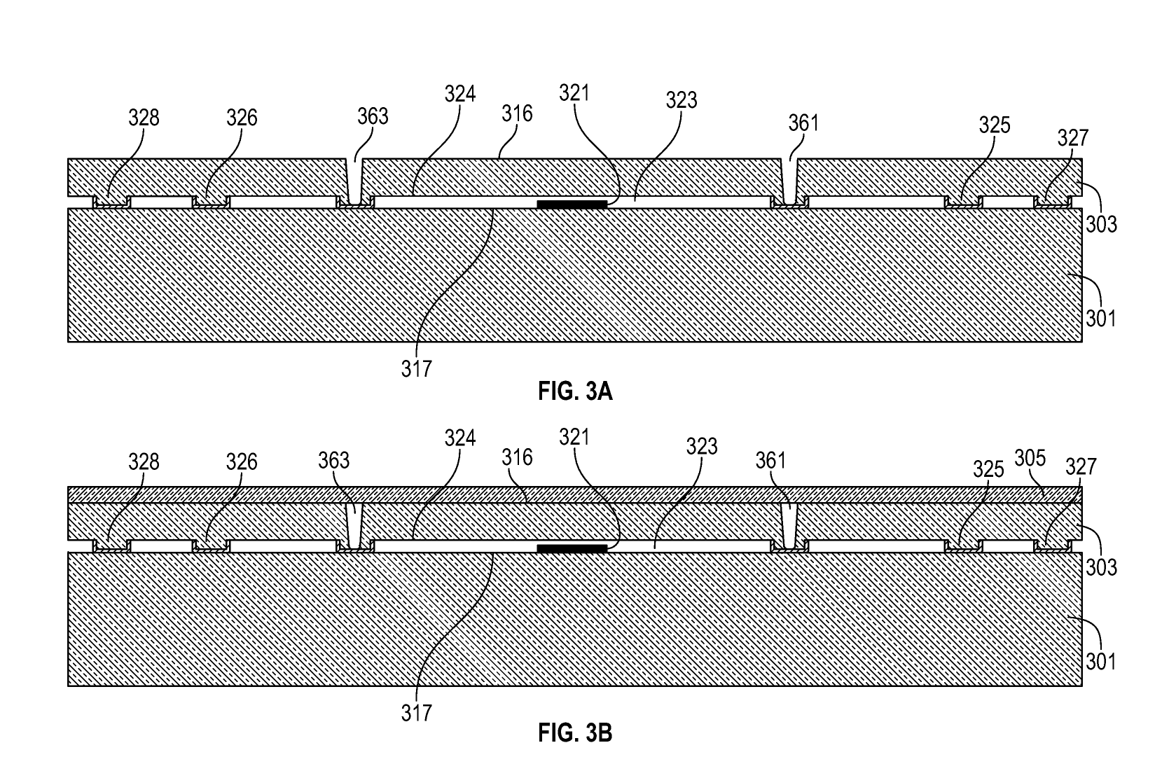

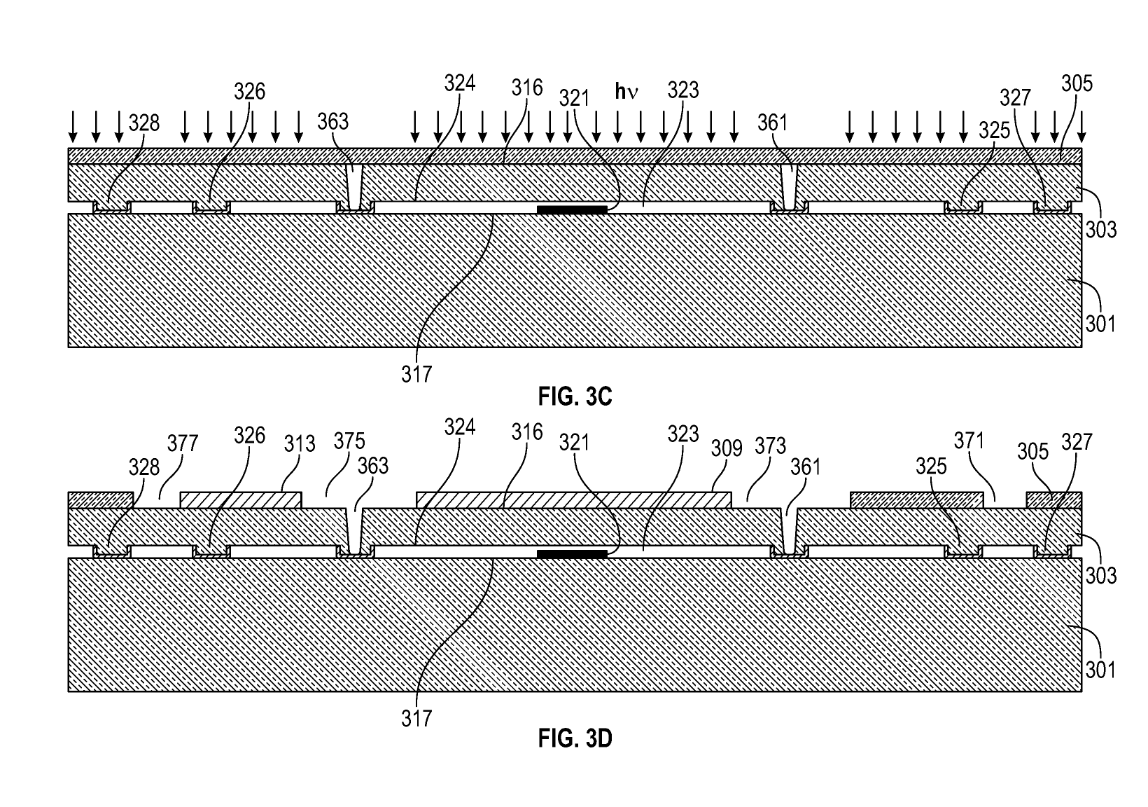

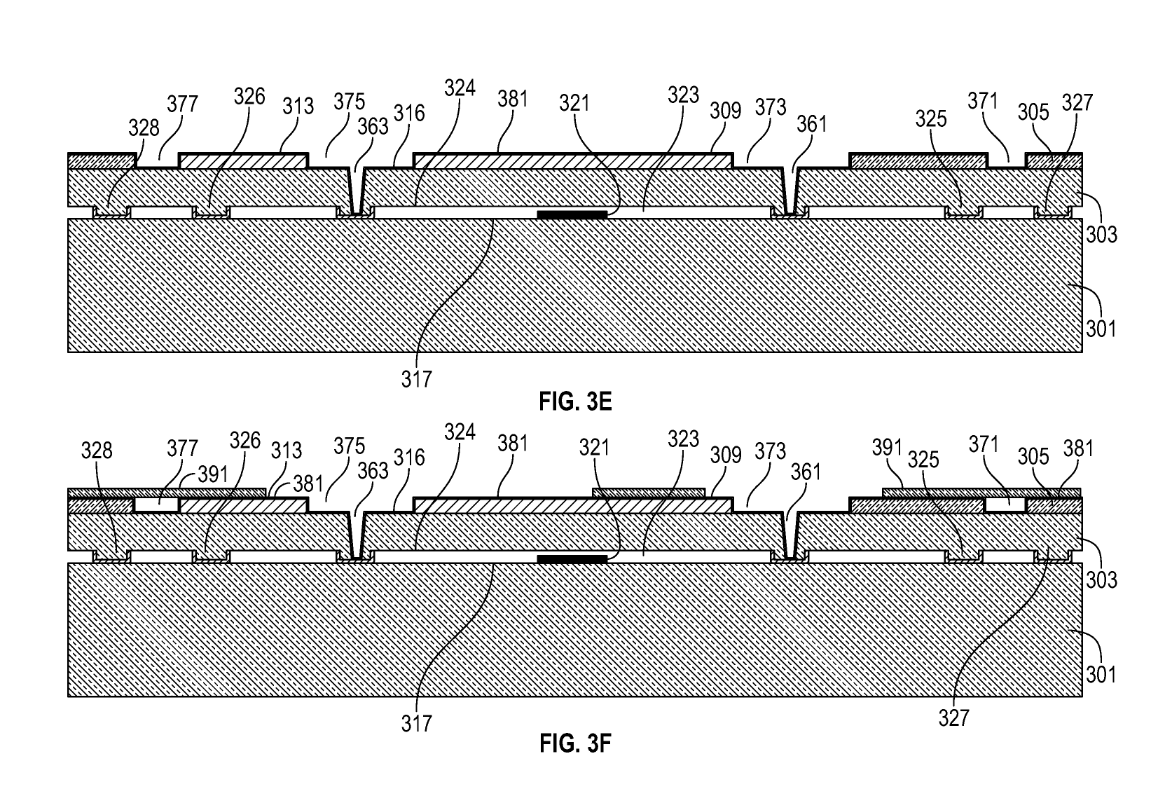

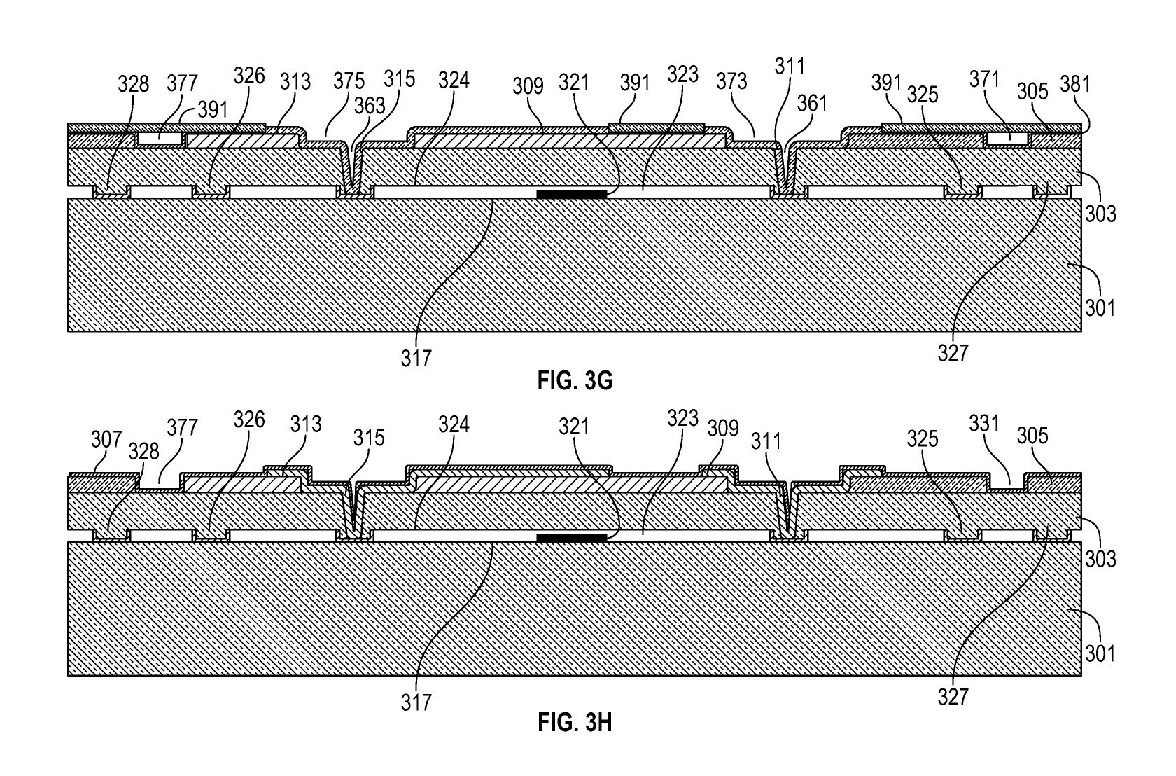

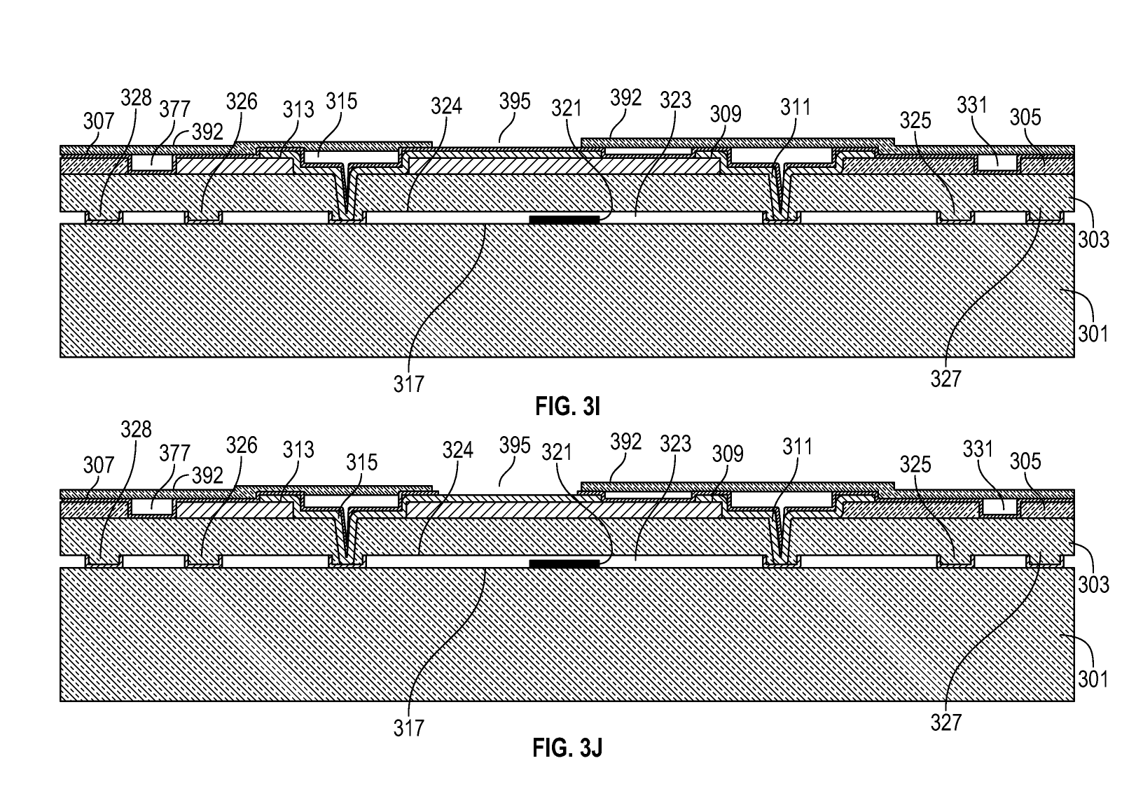

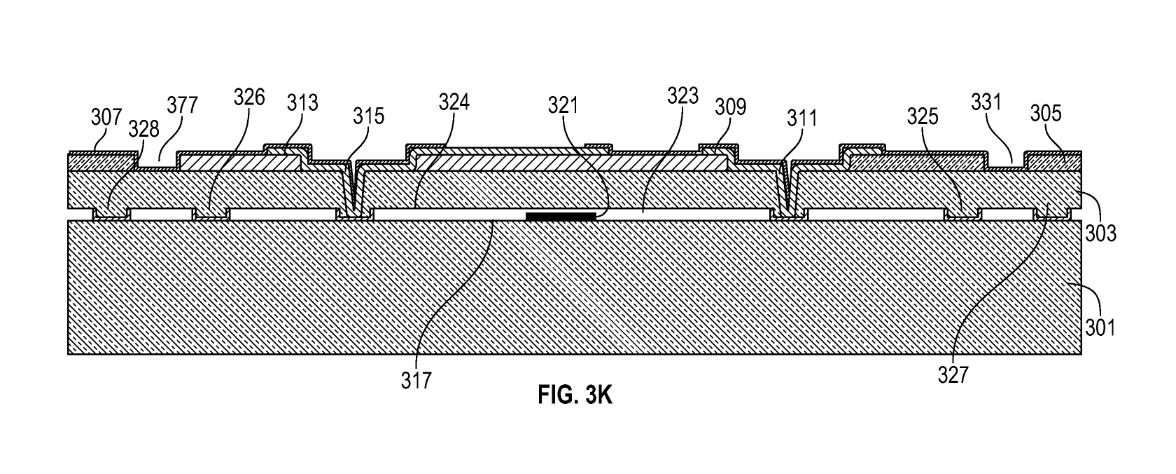

FIGS. 3A-3J are cross-sectional views of a process for fabricating an apparatus according to a representative embodiment.

Turning initially to FIG. 3A, a microcap structure prior to processing according to the present teachings is depicted. The microcap structure comprises a substrate 301, and a lid 303 disposed thereover. An electronic device 321 is disposed in a cavity 323 formed between a lower surface 324 of the lid 303, and the upper surface 317 of the substrate 301. First˜fourth standoffs 325-328, which are illustratively thermal-compression bonded to the upper surface 317 of the substrate 301, border the cavity 323. In this way, the cavity 323 is enclosed, being formed by opposing surfaces 317, 324; and first and second standoffs 325, 326. In certain representative embodiments, by known methods and materials, the lid 303 is adhered to the substrate 301 using first and second standoffs 325, 326 so that the cavity 323 is hermetically sealed to a desired level of hermeticity. The structure comprising the lid 303 disposed over a substrate 301 and providing the cavity 323 is often referred to as a “microcap” structure.

Finally, first and second via openings 361 and 63 are provided through the lid 303 as shown.

Turning to FIG. 3B, an electrically insulating layer 305 is disposed over an upper surface 316 of the lid 303. As noted above, the electrically insulating layer 305 is a negative tone photosensitive material (polymer) that crosslinks and hardens when exposed to UV radiation. In accordance with a representative embodiment, the electrically insulating layer 305 has a thickness in the range of approximately 10 μm to approximately 50 μm. Again, it is emphasized that the use of negative tone photosensitive material (e.g., SU-8) for the electrically insulating layer 305 is merely illustrative, and other materials such as other deposited in a dry film resist (DFR) photosensitive materials, or wet (spin-on) photosensitive materials are contemplated. Moreover, as noted above, other materials that are amenable to for use according to the methods and goals of the present teachings are also contemplated.

Turning to FIG. 3C, in a photolithography step, a mask (not shown) is disposed over regions of the electrically insulating layer 305 to be protected, and an exposure (hu) is effected in the unprotected portions as shown. With exposure over the unmasked portions, the electrically insulating layer 305 (polymer) crosslinks and hardens, preventing its subsequent reflow. Thereafter, a known post-exposure bake is carried out.

Turning to FIG. 3D, after standard processing, unexposed portions of the electrically insulating layer 305 are removed. This step reveals first and second saw street openings 371, 377 in the electrically insulating layer 305; and first and second via openings 373, 375 in the electrically insulating layer 305. As described above, the electrically insulating layer 305 is generally removed from the upper surface 316 in the locations of the first and second saw streets 371,377 to avoid delamination of the electrically insulating layer 305.

Turning to FIG. 3E, a seed layer 381 is disposed conformally over the upper surfaces of the first and second saw streets 371, 377; the electrically insulating layer 305; the first via openings 361, 373; and the second via openings 363, 375. The seed layer 381 is selected based on the desired material to be plated thereover, and is deposited using a known method. For purposes of illustration, the seed layer is titanium copper (Ti/Cu), which is useful for plating of copper thereover.

Turning to FIG. 3F, a photoresist mask 391 is selectively deposited, and prevents plating in covered regions.

Turning to FIG. 3G, a plating sequence is carried out, to plate areas not covered by the photoresist mask 391. This plating step, which is illustratively copper plating, forms first and second contact pads 309, 313; and first and second vias 311, 315 as shown.

Turning to FIG. 3H, after a selective etch (not shown) to remove the seed layer 381, a passivation layer 307 is deposited as shown. As noted above, the passivation layer 307 may be PECVD silicon nitride, or other suitable passivation material.

Turning to FIG. 3I, a photoresist mask 391 is provided to protect the upper surface of the passivation layer 307, and leaving an opening 395 for an electrical contact (not shown in FIG. 3I) to be formed.

Turning to FIG. 3J, a selective etch is carried out to removed the passivation layer 307 in the opening 395.

Turning to FIG. 3K, the photoresist mask 391 is removed, and the opening 395 is ready for further plating to realize an electrical contact (e.g., a copper pillar (not shown)). As will be appreciated, after final formation of the electrical contact in the opening 395, the apparatus 100 is realized.

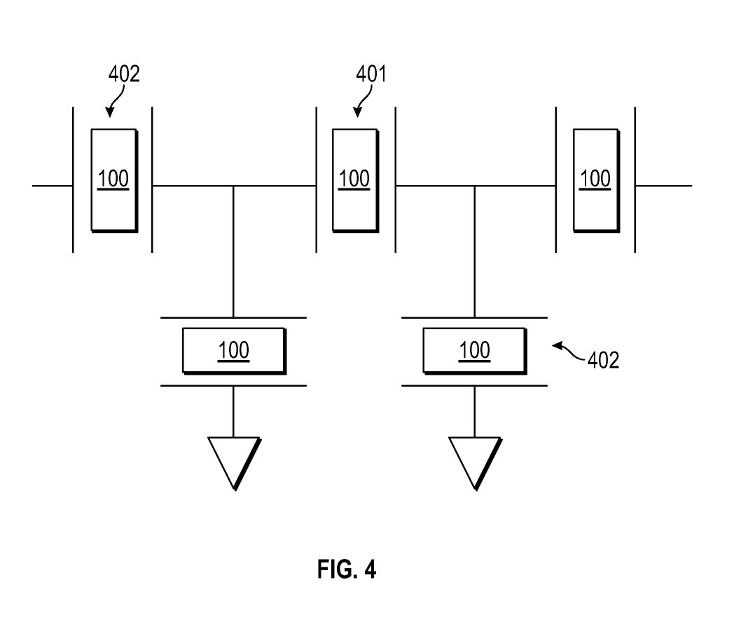

FIG. 4 shows a simplified schematic block diagram of an electrical filter400 in accordance with a representative embodiment. The electrical filter 400 comprises series acoustic resonators 401 and shunt acoustic resonators 402. The series acoustic resonators 401 and shunt acoustic resonators 402 may each comprise described FBAR and SMR acoustic resonators. Notably, the electrical filter 400 could be a component of the electronic devices 121, 221, 321 described in connection with representative embodiments above. As can be appreciated, the electrical filter 400 may be provided over a common substrate and in package form.

The electrical filter 400 is commonly referred to as a ladder filter, and may be used, for example, in duplexer applications. It is emphasized that the topology of the electrical filter 400 is merely illustrative and other topologies are contemplated. Moreover, the acoustic resonators of the representative embodiments are contemplated in a variety of applications including, but not limited to duplexers.

The preceding description of the disclosed embodiments is provided to enable any person skilled in the art to make or use the present disclosure. As such, the above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

We claim:

1. An apparatus, comprising:
a substrate;
a lid disposed over the substrate, and comprising posts disposed around a perimeter of the substrate, the posts enclosing a cavity between the lid and the substrate;
an electronic device disposed over an upper surface of the substrate, and in the cavity;
an electrical contact pad; and
an electrically insulating layer disposed between the electrical contact pad and an upper surface of the lid.

2. The apparatus of claim 1, wherein the electrically insulating layer comprises a polymer material.

3. The apparatus of claim 2, wherein the polymer material is photodefinable.

4. The apparatus of claim 2, wherein the polymer material has a thickness of approximately 10 μm to approximately 50 μm.

5. The apparatus of claim 3, wherein the polymer material is a dry film photoresist material.

6. The apparatus of claim 3, wherein the polymer material is a spin-on material.

7. The apparatus of claim 1, wherein an electrically conducting via exists through the lid, and between the electrical contact pad, and the electrical circuit traces over the upper surface of the substrate.

8. The apparatus of claim 7, wherein the electrically conducting via is a first electrically conducting via, the electrical contact pad is a first electrical contact pad, and the apparatus further comprises:
a second electrical contact pad; and
a second electrically conducting via, which exists through the lid and between the second electrical contact pad, and the electrical circuit traces over the upper surface of the substrate.

9. The apparatus of claim 8, wherein the electrically insulating layer is disposed between the second electrical contact pad and an upper surface of the lid.

10. The apparatus of claim 9, wherein the electrically insulating layer comprises a polymer material.

11. The apparatus of claim 10, wherein the polymer material is photodefinable.

12. The apparatus of claim 10, wherein the polymer material has a thickness of approximately 10 μm to approximately 50 μm.

13. The apparatus of claim 9, further comprising an electrically conductive pillar disposed over the electrically insulating layer, and being electrically connected to the first electrical contact pad, or the second electrical contact pad, or both.

14. The apparatus of claim 1, wherein the lid comprises a semiconductor material.

15. The apparatus of claim 14, wherein areas of the lid beneath an overlap of the electrical contact pad and the electrically insulating layer are substantially free of enhancement or depletion regions.

16. The apparatus of claim 2, wherein a passivation layer is disposed over the polymer material.

17. An apparatus, comprising:
a substrate;
a lid disposed over the substrate, and comprising posts disposed around a perimeter of the substrate, the posts enclosing a cavity between the lid and the substrate;
an electrical filter comprising a plurality of acoustic resonators disposed over an upper surface of the substrate, and in the cavity;
an electrical contact pad; and
an electrically insulating layer disposed between the electrical contact pad and an upper surface of the lid.

18. The apparatus of claim 17, wherein each of the plurality of acoustic resonators is a film bulk acoustic wave resonator (FBAR).

19. The apparatus of claim 17, wherein each of the plurality of acoustic resonators is a solid mount acoustic wave resonator (SMR).

20. The apparatus of claim 17, wherein the electrically insulating layer comprises a polymer material.

21. The apparatus of claim 20, wherein the polymer material is photodefinable.

22. The apparatus of claim 20, wherein the polymer material has a thickness of approximately 10 μm to approximately 50 μm.

23. The apparatus of claim 22, wherein the polymer material is a dry-resist material.

24. The apparatus of claim 22, wherein the polymer material is a spin-on material.

25. The apparatus of claim 17, wherein an electrically conducting via exists through the lid, and between the electrical contact pad, and electrical circuit traces over the upper surface of the substrate.

26. The apparatus of claim 20, wherein a passivation layer is disposed over the polymer material.
